(19) United States
(12) Patent Application Publication
(10) Pub. No.: US 2009/0053891 A1
(43) Pub. Date: Feb. 26, 2009

(54) Method for fabricating a semiconductor device

(75) Inventors: Yi-Chin Lin, Hsinchu City (TW); Chia-Wei Hsu, Hsinchu City (TW); Yeou-Bin Lin, Hsinchu- County (TW); Yi-Tsung Jan, Taipei City (TW); Sung-Min Wei, Hsinchu City (TW); Chin-Cherng Liao, Hsinchu County (TW); Pi-Xuang Chuang, Taichung City (TW); Shih-Ming Chen, Hsinchu City (TW); Hsiao-Ying Yang, Hsinchu City (TW)

Correspondence Address: QUINTERO LAW OFFICE, PC, 2210 MAIN STREET, SUITE 200, SANTA MONICA, CA, 90405, US

(73) Assignee: VANGUARD INTERNATIONAL SEMICONDUCTOR, Hsinchu (TW)

(21) Appl. No.: 12/196,384

(22) Filed: Aug. 22, 2008

(30) Foreign Application Priority Data
Aug. 22, 2007 (TW) TW96131040

(51) Int. Cl. H01L 21/768

(52) U.S. Cl. 438/653; 257/E21.585

(57) ABSTRACT

A method for fabricating a semiconductor device for preventing a poisoned via is provided. A substrate with a conductive layer formed thereon is provided. A composite layer is formed over the substrate and the conductive layer, wherein the composite layer comprises a dielectric layer and a spin-on-glass layer. A via hole is formed through the composite layer, wherein the via hole exposes a surface of the conductive layer. A protection layer is formed on a sidewall of the via hole so as to prevent out-gassing from the spin-on-glass layer. A barrier layer is formed on the protection layer and the conductive layer within the via hole. And a metal layer is deposited on the barrier layer within the via hole to fill the via hole.

### CROSS REFERENCE TO RELATED APPLICATIONS

This Application claims priority of Taiwan Patent Application No. 96131040, filed on Aug. 22, 2007, the entirety of which is incorporated by reference herein.

### BACKGROUND OF THE INVENTION

1. Field of the Invention

The present invention relates to a fabrication method for forming a semiconductor device, and particularly to a fabrication method for forming a via hole in a semiconductor device for preventing out-gassing.

2. Description of the Related Art

Continuing advances in semiconductor manufacturing processes have resulted in semiconductor devices with precision features and/or higher degrees of integration. Among the various features included within a semiconductor device, dielectrics typically provide an electrical isolation between devices and/or metal layers. Dielectric layers are often formed on the substrate comprising conductive layers by chemical vapor deposition (CVD). There may be one or more spin-on-glass layers between the dielectric layers. The spin-on-glass layers are usually used for filling small holes or other defects of the dielectric layers that may reduce electrical efficiency. A composite layer may be formed as a sandwich with various arrangements of the dielectric layers and the spin-on-glass layers.

The composite layer is usually formed as a sandwich with two dielectric layers and one spin-on-glass layer, wherein the spin-on-glass layer is between the dielectric layers. The composite layer may be patterned and etched to form a via hole. The etching rate of the spin-on-glass layer is usually higher than the etching rate of the dielectric layers during an etching process so that the spin-on-glass layer may be etched as a recess on a sidewall within the via hole. A barrier layer may be formed in the via hole by physical vapor deposition with lower cost. In the example, the recess of the spin-on-glass layer in the via hole would become a corner that the barrier layer may not be formed therein, such that the barrier layer will not be entirely formed in the via hole. In this case, reaction gas of the metal layer may react with the spin-on-glass layer not covered by the barrier layer when the via hole is typically filled with a metal layer, and thus out-gassing of the spin-on-glass may occur. As a result, the metal layer may not be deposited in the via hole entirely, and thus the via hole would be “poisoned”.

As described above, a method for preventing a poisoned via hole is needed.

### BRIEF SUMMARY OF THE INVENTION

A detailed description is given in the following embodiments with reference to the accompanying drawings.

The invention provides methods of fabricating a semiconductor device. An exemplary embodiment of a semiconductor device comprises providing a substrate with a conductive layer formed thereon. A composite layer is formed over the substrate and the conductive layer, wherein the composite layer comprises a dielectric layer and a spin-on-glass layer. A via hole is formed through the composite layer, wherein the via hole exposes a surface of the conductive layer. A protection layer is formed on a sidewall of the via hole so as to prevent out-gassing from the spin-on-glass layer. A barrier layer is formed on the protection layer and the conductive layer within the via hole. And a metal layer is deposited on the barrier layer within the via hole to fill the via hole.

### BRIEF DESCRIPTION OF THE DRAWINGS

The present invention can be more fully understood by reading the subsequent detailed description and examples with references made to the accompanying drawings, wherein:

FIGS. 1 to 5 are cross-section views illustrating an exemplary embodiment of a method for forming a via hole for preventing out-gassing according to the invention.

FIG. 6 is a cross-section view illustrating an exemplary embodiment of a method for forming a metal layer in a via hole according to the invention.

### DETAILED DESCRIPTION OF THE INVENTION

Embodiments of the present invention provide methods for forming a via hole for preventing out-gassing. References will be made in detail to the present embodiments, examples of which are illustrated in the accompanying drawings. Wherever possible, the same reference numbers are used in the drawings and the descriptions to refer to the same or like parts. In the drawings, the shape and thickness of one embodiment may be exaggerated for clarity and convenience. The descriptions will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

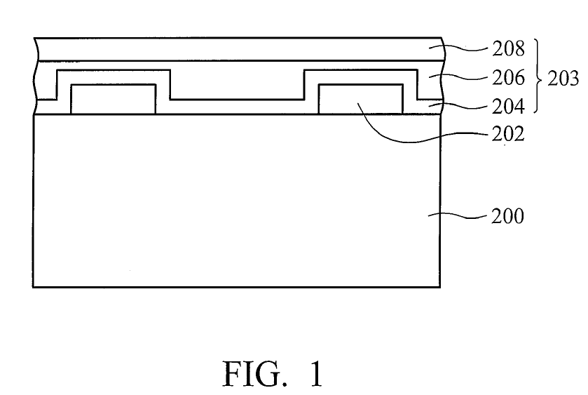

Following, cross-sectional diagrams of FIG. 1 to FIG. 5 illustrate an exemplary embodiment of a method for forming a via hole for preventing out-gassing issues according to the invention.

Referring to FIG. 1, a substrate 200 with a conductive layer 202 thereon is provided. The substrate 200 may comprise silicon. In alternative embodiments, SiGe, bulk semiconductor, strained semiconductor, compound semiconductor, silicon on insulator (SOI), or other commonly used semiconductor substrates can be used for the substrate 200. The substrate 200 may be a substrate comprising transistors, diodes, bipolar junction transistors (BJT), resistors, capacitors, inductors or other electrical elements. The conductive layer 202 may comprise metals, alloys, metal compounds, semiconductor materials or combinations thereof. The conductive layer 202 may comprise basic metals or alloys thereof (such as Cu or Al), refractory metals or alloys thereof (such as Co, Ta, Ni, Ti, W or TiW), transition metal nitrides, refractory metal nitrides (such as CoN, TaN, NiN, TiN or WN), nitride metal silicides (such as CoSi_{X}N_{Y}, TaSi_{X}N_{Y}, NiSi_{X}N_{Y}, TiSi_{X}N_{Y} or WSi_{X}N_{Y}), metal silicides (such as Co-salicide (CoSi_{X}), Ta-salicide (TaSi_{X}), Ni-salicide (NiSi_{X}), Ti-salicide (TiSi_{X}), W-salicide (WSi_{X}), polycrystalline semiconductor materials, amorphous semiconductor materials, phase change materials (such as GaSb, GeTe, Ge₂Sb₂Te₅ or Ag—In—Sb—Te), conductive oxide materials (such as yttrium barium copper oxide (YBCO), Cu₂O, indium tin oxide (ITO)) or combinations thereof.

Referring to FIG. 1, a composite layer 203 comprising a first dielectric layer 204, a second dielectric layer 208, and a spin-on-glass layer 206 is formed on the substrate 200 with the conductive layer 202 formed thereon. The composite layer 203 may comprise one or more dielectric layers and one or more spin-on-glass layers. In a preferred embodiment, the first dielectric layer 204 is formed on the substrate 200 and the conductive layer 202. The spin-on-glass layer 206 is formed on the first dielectric layer 204. Then the second dielectric layer 208 is formed on the spin-on-glass layer 206. An etching-back process may be performed for smoothing a surface of the composite layer 203. The first dielectric layer 204 and the second dielectric layer 208 may be formed by methods, such as chemical vapor deposition (CVD), physical vapor deposition (PVD), atomic layer deposition (ALD), remote plasma enhanced chemical vapor deposition (RPECVD), or liquid source misted chemical deposition (LSMCD). In one example, the first dielectric layer 204 and the second dielectric layer 208 may be formed by plasma enhanced chemical vapor deposition (PECVD). The first dielectric layer 204 and the second dielectric layer 208 may comprise silicon oxide, silicon nitride, silicon oxynitride, amorphous fluorinated carbon, or a combination thereof. The spin-on-glass layer 206 may have two types: organic or inorganic. The spin-on-glass layer 206 of organic type may comprise siloxane. The spin-on-glass layer 206 of inorganic type may comprise silsesquioxane.

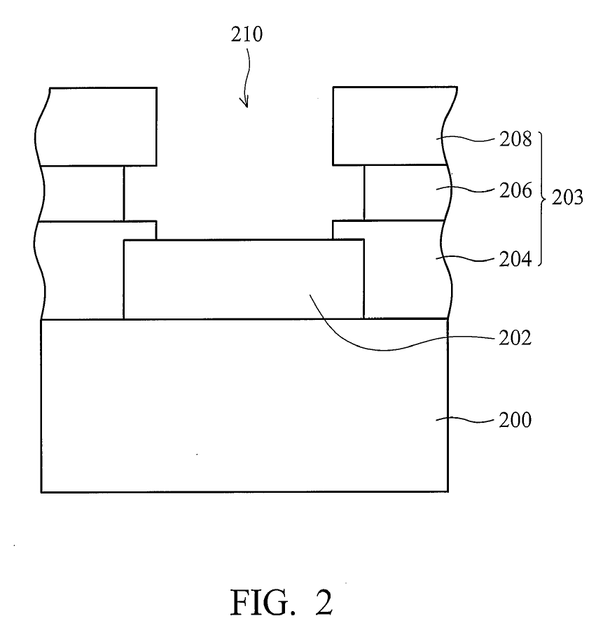

Referring to FIG. 2, a via hole 210 is formed passing through the composite layer 203 to expose a surface of the conductive layer 202. The via hole 210 may be formed by conventional lithography and etching processes. A lithography process may comprise coating a photoresist and pattering the photoresist through steps of exposure and development. The patterned photoresist exposes parts of the composite layer 203 to be removed later. The patterned photoresist may be used to protect the composite layer 203 under the patterned photoresist in processes, such as an etching process for defining the via hole 210. The etching process described above may be an anisotropic or an isotropic etching process. In an exemplary embodiment, since the etching rate of the spin-on-glass layer 206 is faster than etching rates of the first dielectric layer 204 and the second dielectric layer 208, the spin-on-glass layer 206 may be recessed from a sidewall of the via hole 210 between the first dielectric layer 204 and the second dielectric layer 208 during the etching process for forming the via hole 210. The photoresist may be removed after the etching process.

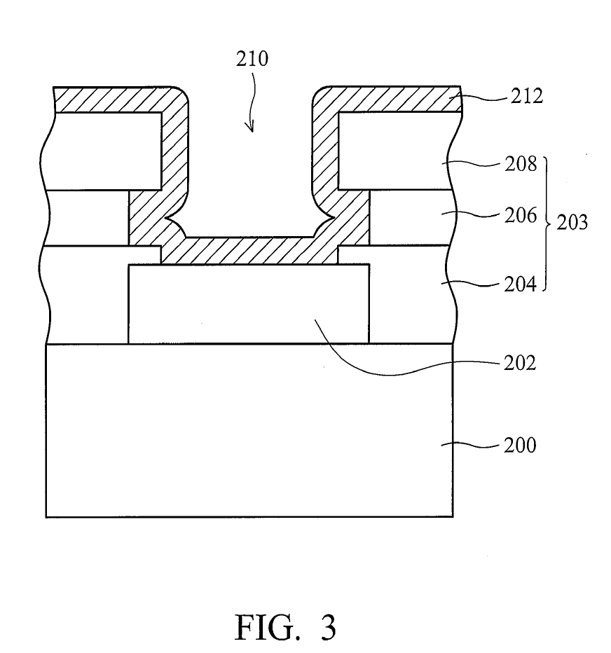

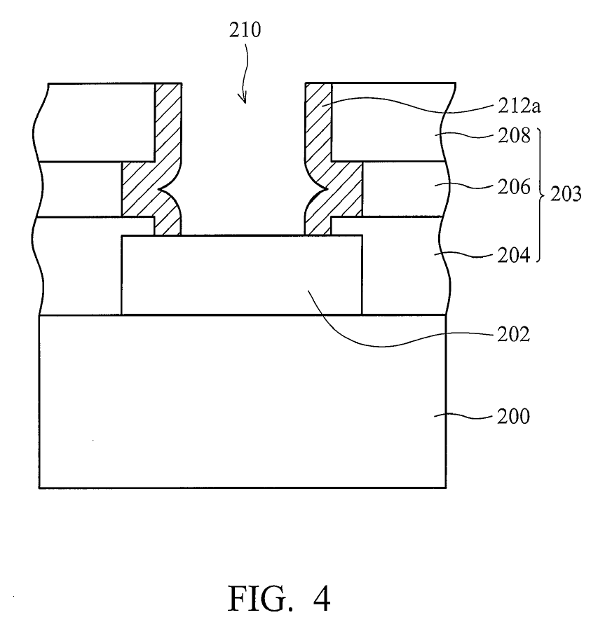

A protection layer 212a is formed on the sidewall of the via hole 210 as shown in FIGS. 3 and 4. For example, a liner oxide layer 212 may be formed by chemical vapor deposition on the sidewall and a bottom of the via hole 210, and is extended to a top surface of the composite layer 203. The liner oxide layer 212 may comprise SiOₓN_{y}.

Referring to FIG. 4, a part of the liner oxide 212 may be removed by applying an etching process to the liner oxide layer 212 within the via hole 210 and on the top surface of the composite layer 203. Then a surface of the conductive layer 202 may be exposed, and a remaining liner oxide layer on the sidewall of the via hole 210 may serve as a protection layer 212a. Within the via hole 210, an etching rate of the liner oxide layer 212 on the composite layer 203 may be slower than an etching rate of the liner oxide layer 212 on the conductive layer 202. Therefore, the etching process may completely remove the liner oxide layer 212 on the conductive layer 202 to expose the surface of the conductive layer 202, and leave a portion of the liner oxide layer to serve as a protection layer 212a on the composite layer 203 within the via hole 210 to completely cover a recess of the spin-on-glass layer 206 so as to prevent out-gassing of the spin-on-glass layer 206. In an exemplary embodiment of the invention, within the via hole 210, a ratio of the etching rate of the liner oxide layer 212 on the composite layer 203 to the etching rate of the liner oxide layer 212 on the conductive layer 202 is preferably about 5 to 20. The protection layer 212a remaining on the composite layer 203 preferably has a thickness of about 50 Å to about 350 Å. In the preferred embodiment, the etching process is preferably a dry etching process and a pre-etching process before depositing of a barrier layer in a chamber that is different from a chamber where a barrier layer is deposited by the same machine at a latter time.

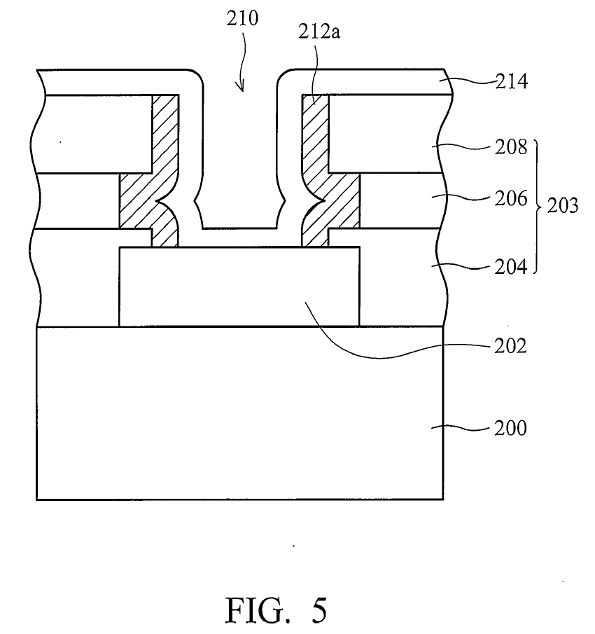

Referring to FIG. 5, a barrier layer 214 is formed on the protection layer 212a and the conductive layer 202 within the via hole 210. In one example, the barrier layer 214 may be formed by physical vapor deposition with lower cost in a chamber that is different from a chamber where the etching process is performed to the liner oxide layer 212a by the same machine. In one embodiment, the barrier layer 214 may comprise TiN.

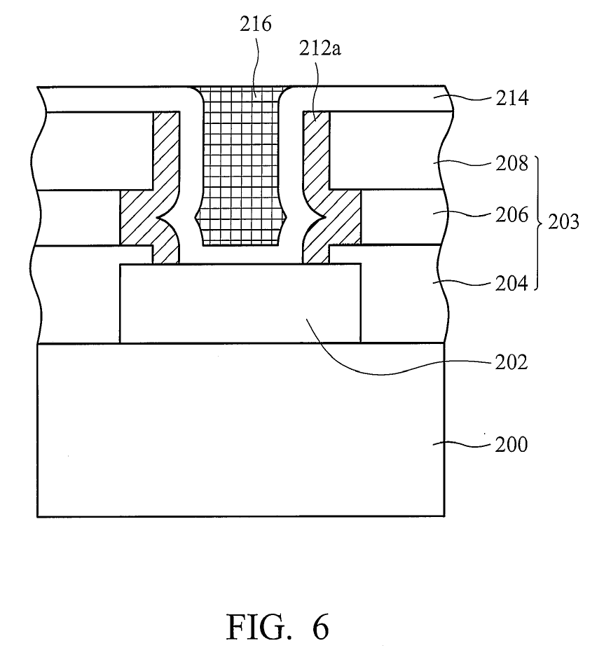

Referring to FIG. 6, a metal layer 216 is formed on the barrier layer 214 to fill the via hole 210. In one example, the metal layer 216 may be formed by conventional chemical vapor deposition. Alternatively, the metal layer 216 on the composite layer 203 may be planarized by, such as a chemical mechanical polish process. The metal layer may comprise Al, Cu, Ta, Ti, Mo, W, Pt, Hf, Ru, or combinations thereof. In one embodiment, the metal layer may be W.

The embodiments of the invention have several advantages, for example, a barrier layer formed by physical vapor deposition with lower cost not covering a recess of a spin-on-glass layer within the via hole can be avoided. Thus, reactive gases of the metal layer would not react with the spin-on-glass layer not covered by the barrier layer, since a protection layer, such as a liner oxide layer, is formed to cover a side wall within a via hole for preventing the occurrence of a poisoned via.

Although the present invention and its advantages have been described in detail, it should be understood that various changes, substitutions and alterations can be made herein without departing from the spirit and scope of the invention as defined by the appended claims. For example, in some applications a different series of ion implantations may be used, as well as different protective layer strategies.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same results as the corresponding embodiments described herein may be utilized according to the present invention. Accordingly, the appended claims are intended to include within their scope such processes, machines, manufacture, compositions of matter, means, methods, or steps.

What is claimed is:

1. A method for fabricating a semiconductor device comprising:
providing a substrate with a conductive layer formed thereon;
forming a composite layer over the substrate and the conductive layer, wherein the composite layer comprises a dielectric layer and a spin-on-glass layer;
forming a via hole through the composite layer to expose a surface of the conductive layer;
forming a protection layer on a sidewall of the via hole so as to prevent out-gassing from the spin-on-glass layer;
forming a barrier layer on the protection layer and the conductive layer within the via hole; and
forming a metal layer on the barrier layer to fill the via hole.

2. The method for fabricating the semiconductor device as claimed in claim 1, wherein the composite layer comprises dielectric layers and at least a spin-on-glass layer is between the dielectric layers.

3. The method for fabricating the semiconductor device as claimed in claim 1, wherein the dielectric layer comprises silicon oxide, silicon nitride, silicon oxynitride, amorphous fluorinated carbon, or a combination thereof.

4. The method for fabricating the semiconductor device as claimed in claim 1, wherein the dielectric layer is formed by plasma enhanced chemical vapor deposition.

5. The method for fabricating the semiconductor device as claimed in claim 1, wherein the spin-on-glass layer comprises an organic material.

6. The method for fabricating the semiconductor device as claimed in claim 5, wherein the organic material comprises siloxane.

7. The method for fabricating the semiconductor device as claimed in claim 1, wherein the spin-on-glass layer comprises an inorganic material.

8. The method for fabricating the semiconductor device as claimed in claim 7, wherein the inorganic material comprises silsesquioxane.

9. The method for fabricating the semiconductor device as claimed in claim 1, wherein the spin-on-glass layer is recessed from the side wall of the via hole under the dielectric layer.

10. The method for fabricating the semiconductor device as claimed in claim 1, wherein the step of forming the protection layer on the sidewall of the via hole comprises:
conformally forming a protection layer on a sidewall and a bottom of the via hole and extending to a top surface of the composite layer; and
performing an etching process to remove a portion of the protection layer until the surface of the conductive layer within the via hole is exposed.

11. The method for fabricating the semiconductor device as claimed in claim 10, wherein the etching process comprises a dry etching process.

12. The method for fabricating the semiconductor device as claimed in claim 10, wherein the protection layer comprises a liner oxide layer.

13. The method for fabricating the semiconductor device as claimed in claim 12, wherein the liner oxide layer comprises SiOₓN_{y}.

14. The method for fabricating the semiconductor device as claimed in claim 12, wherein the liner oxide layer is formed by chemical vapor deposition.

15. The method for fabricating the semiconductor device as claimed in claim 12, wherein the thickness of the liner oxide layer is about 50 angstroms to about 350 angstroms.

16. The method for fabricating the semiconductor device as claimed in claim 12, wherein a ratio of an etching rate of the liner oxide layer on the composite layer to an etching rate of the liner oxide layer on the conductive layer within the via hole is about 5 to 20.
